(19) United States
(12) Patent Application Publication
(10) Pub. No.: US 2011/0237055 A1
(43) Pub. Date: Sep. 29, 2011

(54) Methods of Manufacturing Stacked Semiconductor Devices

(76) Inventors: Yong-hoon Son, Yongin-si (KR); Si-Young Choi, Seongnam-si (KR); Myoung-Bum Lee, Seoul (KR); Ki-Hyun Hwang, Seongnam-si (KR); Seung-Jae Baik, Hwaseong-si (KR); Jeong Hee Han, Hwaseong-si (KR)

(21) Appl. No.: 13/053,291

(22) Filed: Mar. 22, 2011

(30) Foreign Application Priority Data
Mar. 23, 2010 (KR) 10-2010-0025873

(51) Int. Cl. H01L 21/20

(52) U.S. Cl. 438/486; 438/489; 257/E21.09

(57) ABSTRACT

A stacked semiconductor device that is reliable by forming an insulating layer on a lower memory layer and by forming a single crystalline semiconductor in portions of the insulating layer. A method of manufacturing the stacked semiconductor device, including: providing a lower memory layer including a plurality of lower memory structures; forming an insulating layer on the lower memory layer; forming trenches by removing portions of the insulating layer; forming a preparatory semiconductor layer for filling the trenches; and forming a single crystalline semiconductor layer by phase-changing the preparatory semiconductor layer.

### CROSS-REFERENCE TO RELATED APPLICATIONS

This application claims the benefit of Korean Patent Application No. 10-2010-0025873, filed on Mar. 23, 2010, in the Korean Intellectual Property Office, the disclosure of which is incorporated herein in its entirety by reference.

### BACKGROUND

The inventive concept relates to a methods of manufacturing semiconductor devices.

Although the volume of electronic products may gradually decrease, the electronic products may require data processing with increasing capacity. As such, the volume of a semiconductor device used in the electronic products may need to be reduced, and a degree of integration may need to be increased. In this regard, stacked semiconductor devices are considered instead of conventional planar semiconductor devices.

### SUMMARY

According to an aspect of the inventive concept, there are provided methods of manufacturing a stacked semiconductor device. Such methods may include providing a lower memory layer including a plurality of lower memory structures, forming an insulating layer on the lower memory layer, forming trenches by removing portions of the insulating layer, forming a preparatory semiconductor layer for filling the trenches, and forming a single crystalline semiconductor layer by phase-changing the preparatory semiconductor layer. The single crystalline semiconductor layer may include a lower portion including a polycrystalline layer including a plurality of crystalline regions and an upper portion including a single crystalline layer formed by growing one of the plurality of crystalline regions in a single crystalline manner in an upward direction.

In some embodiments, the preparatory semiconductor layer may include an amorphous layer or a polycrystalline layer. The preparatory semiconductor layer may include silicon, silicon-germanium, or germanium.

In some embodiments, forming the insulating layer may include forming an etch stop layer on the lower memory layer and forming the insulating layer on the etch stop layer.

In some embodiments, forming the trenches may include forming the trenches to expose the etch stop layer.

In some embodiments, the insulating layer and the etch stop layer may have different etch selectivities.

In some embodiments, forming the etch stop layer on the lower memory layer may include planarizing the etch stop layer.

In some embodiments, forming the single crystalline semiconductor layer may include melting the preparatory semiconductor layer and growing single crystals from the melted preparatory semiconductor layer. Some embodiments provide that forming the single crystalline semiconductor layer may include forming the single crystalline semiconductor layer by annealing the preparatory semiconductor layer or by irradiating laser on the preparatory semiconductor layer. In some embodiments, forming the single crystalline semiconductor layer may include forming the single crystalline semiconductor layer by using laser epitaxial growth, solid phase-change epitaxy, or metal induced crystallization using a metal catalyst.

In some embodiments, the method may further include, after forming the single crystalline semiconductor layer, forming an upper memory layer including a plurality of upper memory structures for using the single crystalline semiconductor layer for active regions.

In some embodiments, the plurality of upper memory structures may include NAND memory structures, NOR memory structures, dynamic random access memory (DRAM) memory structures, static RAM (SRAM) memory structures, magnetic RAM (MRAM) memory structures, resistive RAM (RRAM) memory structures, or phase change RAM (PRAM) memory structures. The plurality of lower memory structures may include NAND memory structures, NOR memory structures, DRAM memory structures, SRAM memory structures, MRAM memory structures, RRAM memory structures, or PRAM memory structures.

Some embodiments of the inventive concept include methods of manufacturing a stacked semiconductor device. Such methods may include providing a lower memory layer including a plurality of lower memory structures, forming an insulating layer on the lower memory layer, forming trenches by removing portions of the insulating layer, forming a first preparatory semiconductor layer in portions of the trenches, forming a first single crystalline semiconductor layer by phase-changing the first preparatory semiconductor layer, forming a second preparatory semiconductor layer on the first single crystalline semiconductor layer, and forming a second single crystalline semiconductor layer by phase-changing the second preparatory semiconductor layer. The first single crystalline semiconductor layer may include a lower portion including a polycrystalline layer including a plurality of crystalline regions and an upper portion including a single crystalline layer formed by growing one of the plurality of crystalline regions in a single crystalline manner in an upward direction.

In some embodiments, forming the first preparatory semiconductor layer may include forming a preparatory semiconductor material layer in the trenches to fill the trenches and forming the first preparatory semiconductor layer recessed in the trenches by etching the preparatory semiconductor material layer.

In some embodiments, the second preparatory semiconductor layer may be formed to fill the trenches.

In some embodiments, forming the first single crystalline semiconductor layer and forming the second single crystalline semiconductor layer may include forming the first single crystalline semiconductor layer and forming the second single crystalline semiconductor layer insulating layer by respectively annealing the first preparatory semiconductor layer and the second preparatory semiconductor layer or by respectively irradiating laser on the first preparatory semiconductor layer and the second preparatory semiconductor layer.

In some embodiments, the first single crystalline semiconductor layer and the second single crystalline semiconductor layer may have a crystalline structure in which the first single crystalline semiconductor layer and the second single crystalline semiconductor layer are coherent.

In some embodiments, one of the first single crystalline semiconductor layer and the second single crystalline semiconductor layer may include a strained layer.

Some embodiments of the inventive concept include methods of manufacturing a stacked semiconductor device. Such methods may include providing a semiconductor layer including a plurality of lower memory structures, forming a preparatory semiconductor layer on the semiconductor layer, and forming a single crystalline semiconductor layer by phase-changing the preparatory semiconductor layer. The single crystalline semiconductor layer may include a lower portion including a polycrystalline layer including a plurality of crystalline regions and an upper portion including a single crystalline layer formed by growing one of the plurality of crystalline regions in a single crystalline manner in an upward direction.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a stacked semiconductor device according to some embodiments of the inventive concept;

FIG. 2 is a layout diagram of a part of a memory cell array of the stacked semiconductor device illustrated in FIG. 1, according to some embodiments of the inventive concept;

FIGS. 3 and 4 are cross-sectional views taken along lines III-III′ and IV-IV′ of FIG. 2, according to some embodiments of the inventive concept;

FIGS. 5A through 5F are cross-sectional views for illustrating a method of manufacturing the stacked semiconductor device illustrated in FIG. 1, according to some embodiments of the inventive concept;

FIG. 6 is an enlarged cross-sectional view of a region A of FIG. 5F, illustrating the structure of a single crystalline semiconductor layer;

FIGS. 7A through 7E are cross-sectional views for illustrating methods of manufacturing the stacked semiconductor device illustrated in FIG. 1, according to some embodiments of the inventive concept;

FIG. 8 is a schematic diagram of a memory card according to some embodiments of the inventive concept; and

FIG. 9 is a schematic diagram of a system according to some embodiments of the inventive concept.

### DETAILED DESCRIPTION OF THE EMBODIMENTS

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

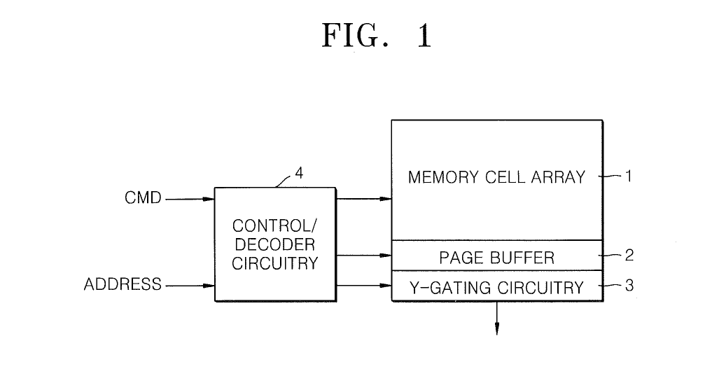

FIG. 1 is a block diagram of a stacked semiconductor device according to some embodiments of the inventive concept.

Referring to FIG. 1, the stacked semiconductor device may include a memory cell array 1, a page buffer 2, a Y-gating circuitry 3, and a control/decoder circuitry 4.

The memory cell array 1 may include a plurality of memory blocks, and each of the plurality of memory blocks may include a plurality of nonvolatile memory cells. The nonvolatile memory cells may be flash memory cells, for example, NAND flash memory cells, and/or NOR flash memory cells. The page buffer 2 may temporarily store data to be written in the memory cell array 1, and/or data to be read from the memory cell array 1. The Y-gating circuitry 3 may transmit data stored in the page buffer 2. The control/decoder circuitry 4 may receive a command and an address from the outside, output a control signal to write data in the memory cell array 1 and/or to read data from the memory cell array 1, and decode the address. The control/decoder circuitry 4 may output a control signal for input and output of data to the page buffer 2 and provide address information to the Y-gating circuitry 3.

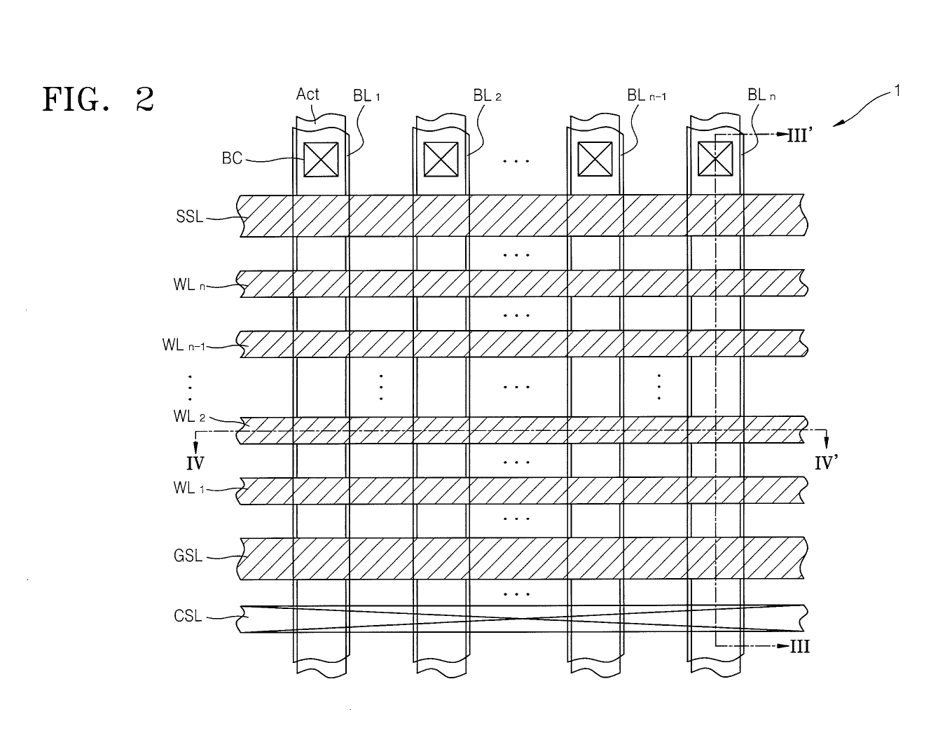

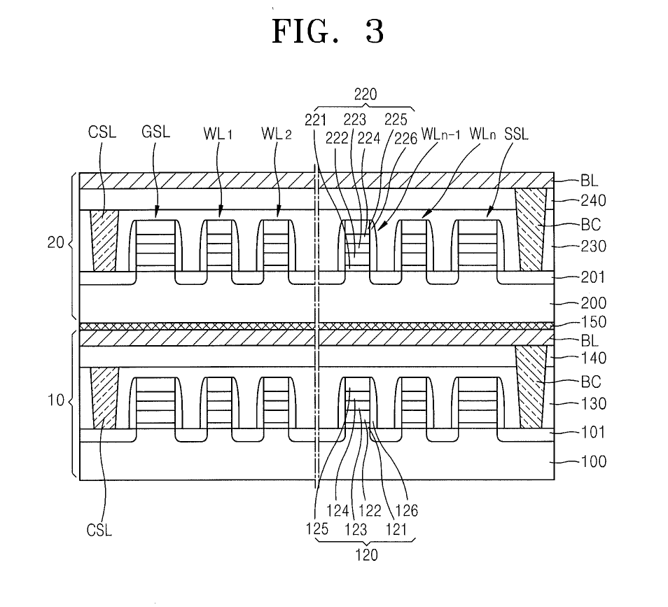

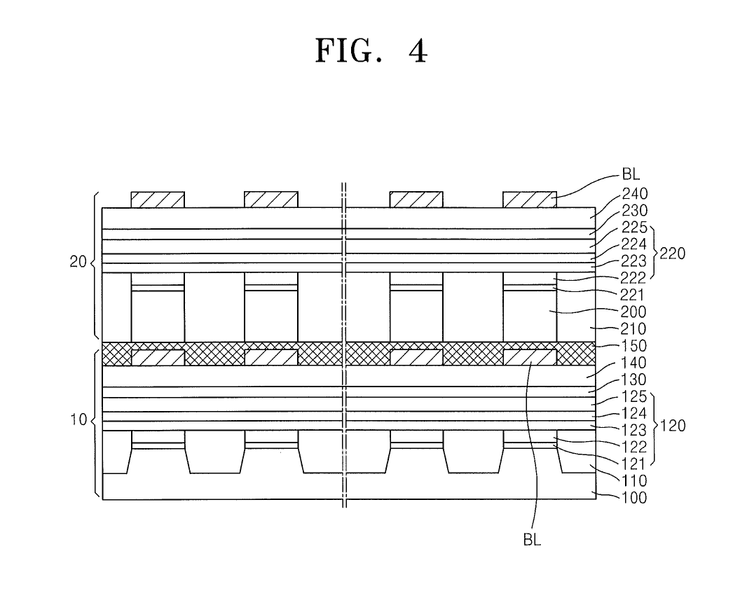

FIG. 2 is a layout diagram of a portion of a memory cell array 1 of the stacked semiconductor device illustrated in FIG. 1, according to some embodiments of the inventive concept. The portion of the memory cell array 1 shown in FIG. 2 may be a portion of the memory cell array 1 in FIG. 1. FIGS. 3 and 4 are cross-sectional views taken along lines III-III′ and IV-IV′ of FIG. 2, according to some embodiments of the inventive concept.

Referring to FIGS. 2, 3, and 4, the memory cell array 1 may include a lower memory layer 10 and an upper memory layer 20, which are stacked facing each other. The lower memory layer 10 may include a plurality of lower memory structures 120, and the upper memory layer 20 may include a plurality of upper memory structures 220.

The memory cell array 1 may include a plurality of active regions Act that are defined by device isolation layers 110 formed in a lower semiconductor layer 100 or by device isolation layers 210 formed in an upper semiconductor layer 200. The lower semiconductor layer 100 may include a substrate and/or an epitaxial layer, a silicon-on-insulator (SOI) layer, semiconductor-on-insulator (SeOI) layer, or the like. The active regions Act may have the form of parallel lines. The upper semiconductor layer 200 may be formed of a single crystalline material, as described below, and may include silicon, silicon-germanium, or germanium, for example.

A string selection line SSL and a ground selection line GSL may extend across over the active regions Act. A plurality of word lines WL₁, WL₂, . . . , WLₙ₋₁, and WLₙ may extend across over the active regions Act, between the string selection line SSL and the ground selection line GSL. The string selection line SSL, the ground selection line GSL, and the word lines WL₁, WL₂, . . . , WLₙ₋₁, and WLₙ may be parallel to one another. Impurity regions 101 and 201 may be formed in the active regions Act adjacent to both sides of each of the word lines WL₁, WL₂, . . . , WLₙ₋₁, and WLₙ, the string selection line SSL, and the ground selection line GSL. As a result, a string selection transistor, cell transistors, and a ground selection transistor that are connected in series are formed. The string selection transistor, the ground selection transistor, and the cell transistors interposed therebetween may constitute a unit memory block. The impurity regions 101 and 201 disposed adjacent to the string selection line SSL and opposite to the ground selection line GSL may be defined as drain regions of the string selection transistor. Also, the impurity regions 101 and 201 disposed adjacent to the ground selection line GSL and opposite to the string selection line SSL may be defined as source regions of the ground selection transistor.

Each of the word lines WL₁, WL₂, . . . , WLₙ₋₁, and WLₙ may include a tunneling insulating layer 121, a charge storage layer 122, a blocking insulating layer 123, and a gate electrode layer 124 that are stacked sequentially in the stated order on the lower semiconductor layer 100. Also, each of the word lines WL₁, WL₂, . . . , WLₙ₋₁, and WLₙ may include a tunneling insulating layer 221, a charge storage layer 222, a blocking insulating layer 223, and a gate electrode layer 224 that are stacked sequentially in the stated order on the upper semiconductor layer 200. Also, each of the word lines WL₁, WL₂, . . . , WLₙ₋₁, and WLₙ may further include capping layers 125 and 225 formed on the gate electrode layers 124 and 224.

Each of the tunneling insulating layers 121 and 221 and each of the charge storage layers 122 and 222 may be separated into portions with respect to the cell transistors disposed adjacently in the direction of the word lines WL₁, WL₂, . . . , WLₙ₋₁, and WLₙ. Top surfaces of the device isolation layers 110 and 210 may be at substantially the same level as top surfaces of the charge storage layers 122 and 222. The tunneling insulating layers 121 and 221 may be silicon oxide layers, silicon-germanium oxide layer, or germanium oxide layers. The charge storage layers 122 and 222 may be charge trapping layers or floating gate conductive layers. The blocking insulating layers 123 and 223 may be shared among the cell transistors disposed adjacently in the direction of the word lines WL₁, WL₂, . . . , WLₙ₋₁, and WLₙ. The blocking insulating layers 123 and 223 may have a multi-layer structure, and for example, a multi-layer structure each including a silicon oxide and a high-k dielectric. Spacers 126 and 226 may be disposed on side surfaces of the tunneling insulating layers 121 and 221, the charge storage layers 122 and 222, the blocking insulating layers 123 and 223, and the gate electrode layers 124 and 224. The spacers 126 and 226 may be formed as multi-layers.

The string selection line SSL and the ground selection line GSL may have the same stacked structures as the word lines WL₁, WL₂, . . . , WLₙ₋₁, and WLₙ described above. In some embodiments, widths of the string selection line SSL and the ground selection line GSL may each be greater than those of the word lines WL₁, WL₂, . . . , WLₙ₋₁, and WLₙ. However, this is by way of example and the inventive concept is not limited thereto.

First interlayer insulating layers 130 and 230 are provided on the word lines WL₁, WL₂, . . . , WLₙ₋₁, and WLₙ, the string selection line SSL and the ground selection line GSL. A common source line CSL is disposed through the first interlayer insulating layers 130 and 230 and connected to the source region of the ground selection line GSL. The common source line CSL may be disposed parallel to the ground selection line GSL. Second interlayer insulating layers 140 and 240 may be provided on the first interlayer insulating layers 130 and 230, respectively. A bit line plug BC may be disposed through the second interlayer insulating layers 140 and 240 and the first interlayer insulating layers 130 and 230 and connected to the drain region of the string selection line SSL. Bit lines BL₁, BL₂, . . . , BLₙ₋₁, and BLₙ may be disposed on the second interlayer insulating layers 140 and 240, respectively, and connected to the bit line plug BC. Also, the bit lines BL₁, BL₂, . . . , BLₙ₋₁, and BLₙ extend across over the word lines WL₁, WL₂, . . . , WLₙ₋₁, and WLₙ. The bit lines BL₁, BL₂, . . . , BLₙ₋₁, and BLₙ may be disposed parallel to the active regions Act. An etch stop layer 150 is disposed between the lower memory layer 10 and the upper memory layer 20. The etch stop layer 150 may include an oxide, a nitride, and/or an oxynitride, among others.

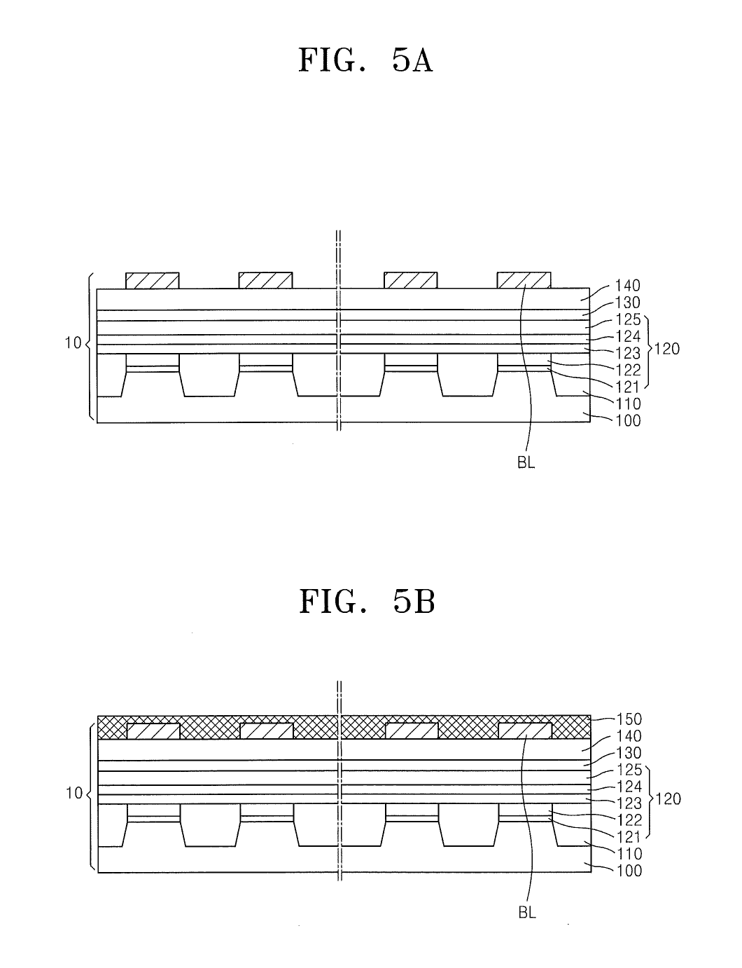

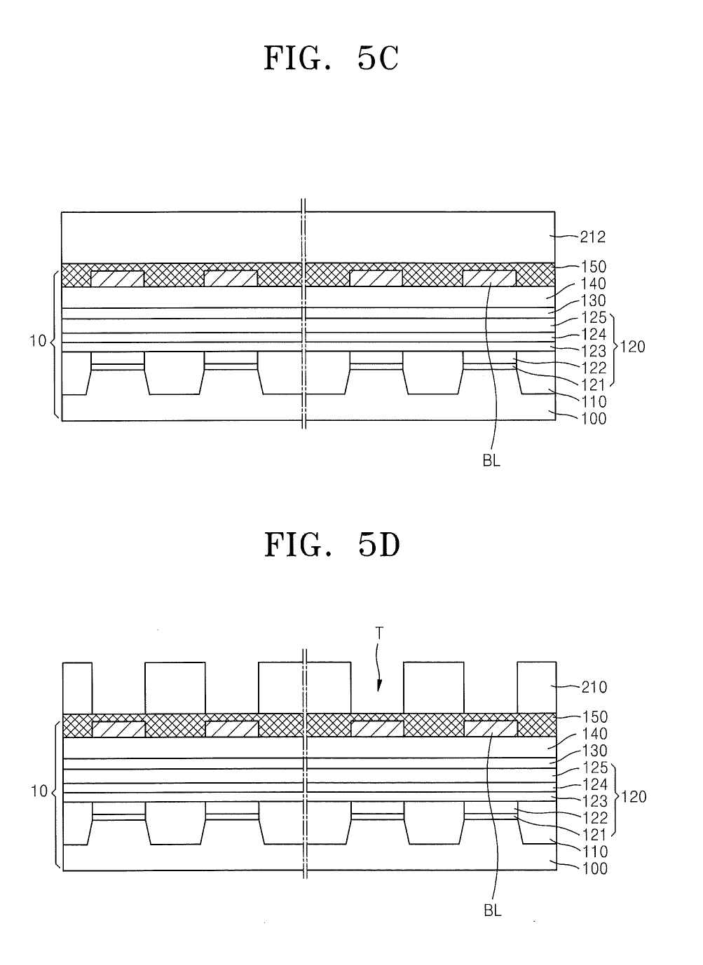

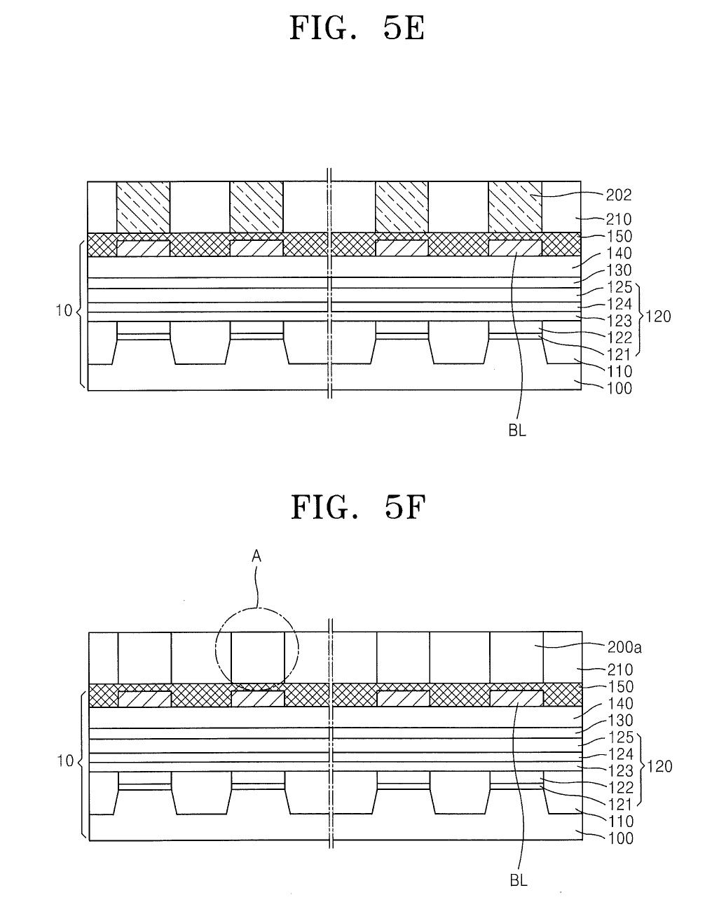

FIGS. 5A through 5F are cross-sectional views for illustrating methods of manufacturing the stacked semiconductor device illustrated in FIG. 1, according to some embodiments of the inventive concept.

Referring to FIG. 5A, the lower memory layer 10 including the lower memory structures 120 is provided. As described above, the lower memory structures 120 may be NAND memory structures. In this case, the lower memory structures 120 may each include the tunneling insulating layer 121, the charge storage layer 122, the blocking insulating layer 123, and the gate electrode layer 124. The lower memory structures 120 may further include the first interlayer insulating layer 130 and the second interlayer insulating layer 140 respectively provided on the lower memory structures 120. The lower memory structures 120 may further include a bit line BL electrically connected to the lower memory structures 120. However, it is exemplary that the lower memory structures 120 are the NAND memory structures, and the inventive concept is not limited thereto. For example, the lower memory structures 120 may include NOR memory structures, dynamic random access memory (DRAM) memory structures, static RAM (SRAM) memory structures, magnetic RAM (MRAM) memory structures, resistive RAM (RRAM) memory structures, or phase change RAM (PRAM) memory structures.

Referring to FIG. 5B, the etch stop layer 150 is formed on the lower memory layer 10. The etch stop layer 150 is formed to cover the bit line BL. The etch stop layer 150 may include an oxide, a nitride, and/or an oxynitride and may include at least one selected from the group consisting of, for example, a silicon oxide (SiO₂), a silicon nitride (Si₃N₄), a silicon oxynitride (SiON), an aluminum oxide (Al₂O₃), an aluminum nitride (AlₓN_{y}), a hafnium oxide (HfO₂), a hafnium silicon oxide (HfSiₓO_{y}), a hafnium silicon oxynitride (HfSiON), a hafnium oxynitride (HfON), a hafnium aluminum oxide (HfAlₓO_{y}), a zirconium oxide (ZrO₂), a tantalum oxide (Ta₂O₃), a hafnium tantalum oxide (HfTaₓO_{y}), a lanthanum oxide (La₂O₃), a lanthanum aluminum oxide (LaAlO), a lanthanum hafnium oxide (LaHfO), a hafnium aluminum oxide (HfAlO), and/or a metal oxide, among others. Also, the etch stop layer 150 may be optionally planarized using an etch-back or chemical mechanical polishing (CMP) process.

Referring to FIG. 5C, an insulating layer 212 is formed on the lower memory layer 10. When the etch stop layer 150 is present in the lower memory layer 10, the insulating layer 212 is formed on the etch stop layer 150. The insulating layer 212 may be formed using chemical vapor deposition (CVD), low pressure CVD (LPCVD), plasma enhanced CVD (PECVD), atomic layer deposition (ALD), or sputtering. The insulating layer 212 may include an oxide, a nitride, or an oxynitride and may include at least one selected from the group consisting of, for example, a silicon oxide (SiO₂), a silicon oxynitride (SiON), a silicon nitride (Si₃N₄), an aluminum oxide (Al₂O₃), an aluminum nitride (AlₓN_{y}), a hafnium oxide (HfO₂), a hafnium silicon oxide (HfSiₓO_{y}), a hafnium silicon oxynitride (HfSiON), a hafnium oxynitride (HfON), a hafnium aluminum oxide (HfAlₓO_{y}), a zirconium oxide (ZrO₂), a tantalum oxide (Ta₂O₃), a hafnium tantalum oxide (HfTaₓO_{y}), a lanthanum oxide (La₂O₃), a lanthanum aluminum oxide (LaAlO), a lanthanum hafnium oxide (LaHfO), a hafnium aluminum oxide (HfAlO), and/or a metal oxide, among others. In some embodiments, the insulating layer 212 and the etch stop layer 150 may have different etch selectivities. For example, when the etch stop layer 150 includes a silicon nitride (Si₃N₄), the insulating layer 212 may include a silicon oxide (SiO₂) having a different selectivity from that of the silicon nitride (Si₃N₄).

Referring to FIG. 5D, trenches T are formed by removing portions of the insulating layer 212. Although not shown, the trenches T may be formed by forming a mask pattern layer (not shown) on the insulating layer 212 and then etching exposed portions of the insulating layer 212 by using the mask pattern layer as an etch mask. As described above, the insulating layer 212 and the etch stop layer 150 have different etch selectivities and thus the etching process may be finished at the etch stop layer 150. Thus, the etch stop layer 150 may be exposed by the trenches T. Remaining portions of the insulating layer 212 that are not etched by the etching process may be the device isolation layers 210.

Referring to FIG. 5E, a preparatory semiconductor layer 202 is formed in at least portions of the trenches T. In some embodiments, the preparatory semiconductor layer 202 is formed to fill the trenches T. The preparatory semiconductor layer 202 may be an amorphous layer and/or a polycrystalline layer. The preparatory semiconductor layer 202 may be formed using CVD, LPCVD, PECVD, ALD, and/or sputtering.

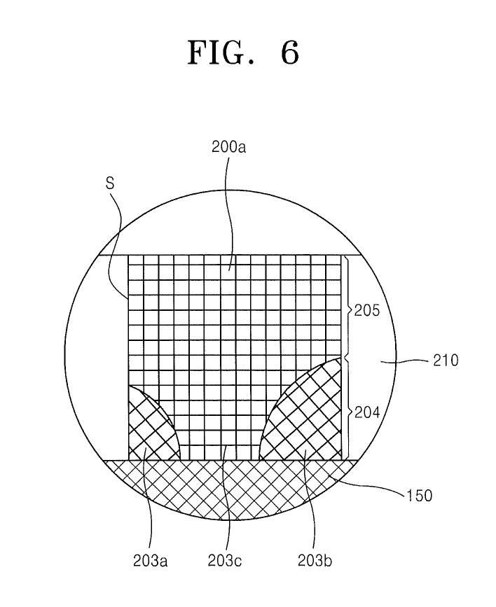

Referring to FIG. 5F, a single crystalline semiconductor layer 200a is formed by phase-changing the preparatory semiconductor layer 202. For example, the single crystalline semiconductor layer 200a may be formed by annealing the preparatory semiconductor layer 202 to phase-change at least portions of the preparatory semiconductor layer 202 into the single crystalline semiconductor layer 200a. The single crystalline semiconductor layer 200a may correspond to the upper semiconductor layer 200 described above. The annealing process may be performed using a furnace. When the furnace is used to perform the annealing process, the preparatory semiconductor layer 202 is annealed at a temperature of 600° C. to 700° C. for several hours, thereby phase-changing the preparatory semiconductor layer 202 that is the amorphous layer or polycrystalline layer into the single crystalline semiconductor layer 200a. Also, the phase-changing process may be performed using laser epitaxial growth, solid phase-change epitaxy, or metal induced crystallization using a metal catalyst. The single crystalline semiconductor layer 200a will be described later with reference to FIG. 6 in detail.

When a laser epitaxial growth process is performed, laser may have an energy density at which the preparatory semiconductor layer 202 may be completely melted. In detail, when the preparatory semiconductor layer 202 is melted by irradiating laser beams thereon, the preparatory semiconductor layer 202 that is the amorphous layer or polycrystalline layer is changed from a solid state to a liquid state. For example, the laser beams may be irradiated in such a way that a melting point of silicon is equal to or higher than about 1,410° C. Subsequently, when the annealing process is finished, for example, when laser irradiation is finished or the degree of laser irradiation is reduced, single crystals may be grown from a lower side surface of the melted preparatory semiconductor layer 202. As such, the single crystalline semiconductor layer 200a may be formed. An element for irradiating the laser beams may be excimer laser, which is a type of gaseous laser. Also, the laser member may have a structure in which scanning may be performed. This is because the laser beams may be irradiated within a short time. Also, when the laser beams are irradiated on the preparatory semiconductor layer 202, the lower memory layer 10 may be heated. In this way, the lower memory layer 10 is heated to reduce a temperature gradient in a thin film in which phase change occurs, when the preparatory semiconductor layer 202 is phase-changed by irradiating the laser beams thereon. For example, the lower memory layer 10 may be heated at a temperature of about 400° C.

Subsequently, the upper memory layer 20 is formed on the lower memory layer 10, thereby completing the structures illustrated in FIGS. 3 and 4. The upper memory layer 20 includes the upper memory structures 220. In the upper memory structures 220, the single crystalline semiconductor layer 200a may be used for active region, such as a source/drain region or a channel region. As described above, the upper memory structures 220 may be NAND memory structures. In this case, the upper memory structures 220 may each include the tunneling insulating layer 221, the charge storage layer 222, the blocking insulating layer 223, and the gate electrode layer 224. Also, the upper memory structures 220 may each further include the first interlayer insulating layer 230 and the second interlayer insulating layer 240 respectively provided on the upper memory structures 220. Also, the upper memory structures 220 may further include the bit line BL electrically connected to the upper memory structures 220. However, it is exemplary that the upper memory structures 220 are the NAND memory structures, and the inventive concept is not limited thereto. For example, the upper memory structures 220 may include NOR memory structures, DRAM memory structures, SRAM memory structures, MRAM memory structures, RRAM memory structures, and/or PRAM memory structures.

FIG. 6 is an enlarged cross-sectional view of a region A of FIG. 5F, illustrating the structure of the single crystalline semiconductor layer 200a. Referring to FIG. 6, the single crystalline semiconductor layer 200a may include a lower portion 204 including a polycrystalline layer having a plurality of crystalline regions 203a, 203b, and 203c, and an upper portion 205 including a single crystalline layer formed by growing one of the plurality of crystalline regions 203a, 203b, and 203c in a single crystalline manner in an upward direction. In detail, when the preparatory semiconductor layer 202 is annealed to be phase-changed into the single crystalline semiconductor layer 200a, the preparatory semiconductor layer 202 may be melted and then solidified again. When the preparatory semiconductor layer 202 is solidified, nuclear generation and crystal growth of the plurality of crystalline regions 203a, 203b, and 203b may be performed in the lower portion 204. As such, a polycrystalline layer may be formed. While the crystal growth is performed, the crystal growth of the crystalline regions 203a and 203b that are not parallel to sidewalls S of the trenches T may be stopped due to the sidewalls S. On the other hand, the crystal growth of the crystalline regions 203c that are parallel to the sidewalls S may be continuously performed in an upward direction and/or a lateral direction. As such, a single crystalline layer that is grown from the crystalline regions 203c may be formed in the upper portion 205 of the single crystalline semiconductor layer 200a. It is understood by one of ordinary skill in the art that annealing conditions, such as temperature conditions of the furnace and/or laser irradiation conditions, are adjusted so as to form the single crystalline layer.

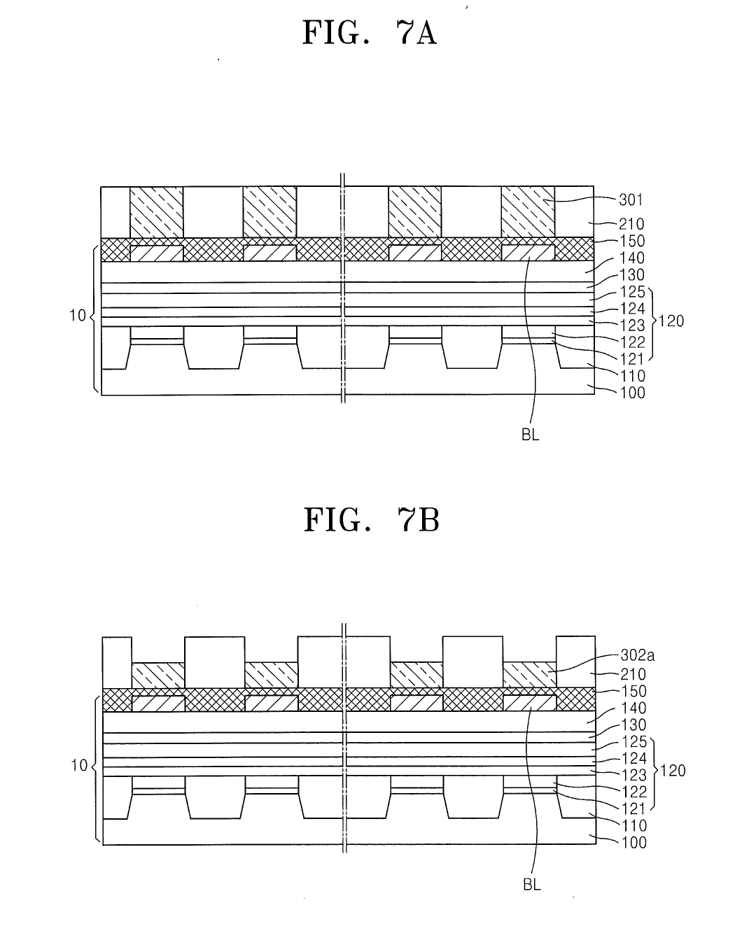

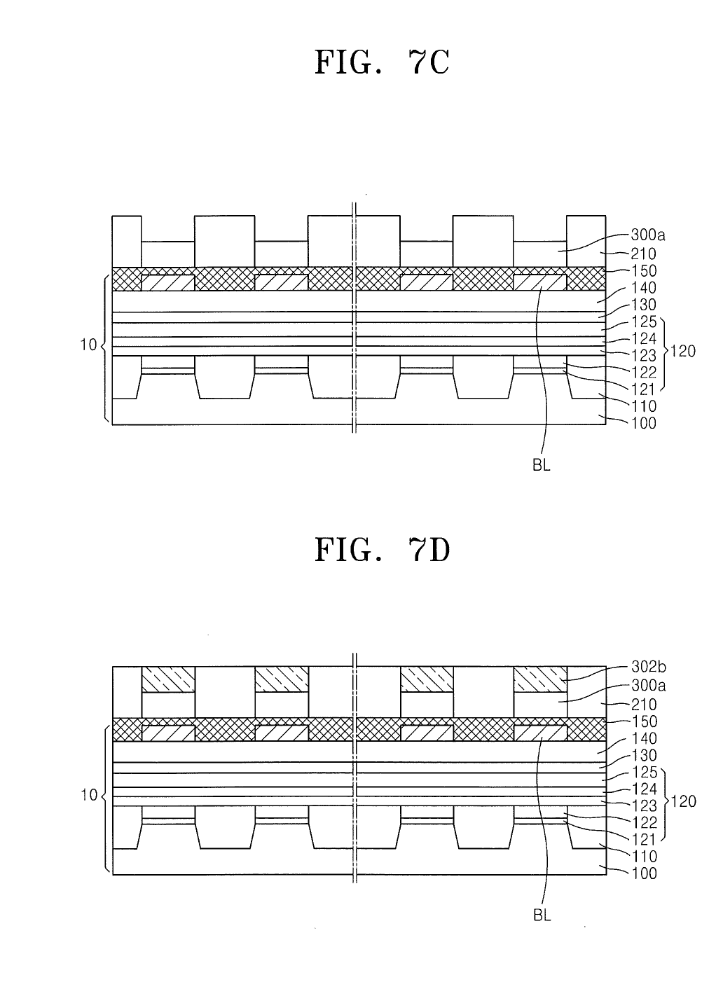

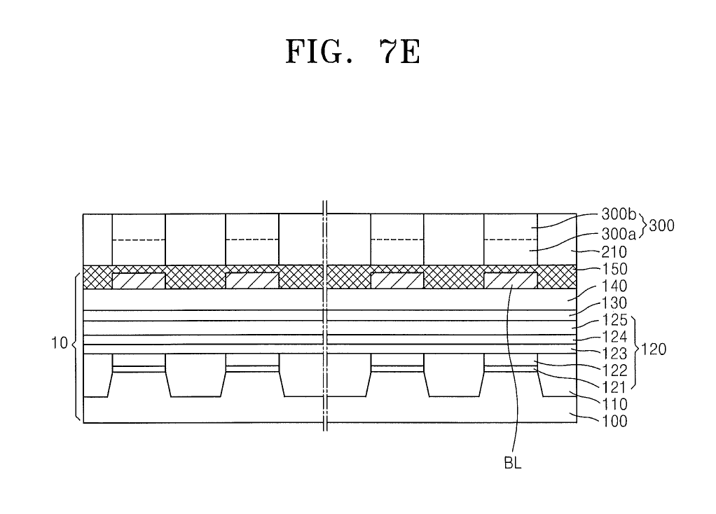

FIGS. 7A through 7E are cross-sectional views for illustrating methods of manufacturing the stacked semiconductor device illustrated in FIG. 1, according to another embodiment of the inventive concept. The method of manufacturing the stacked semiconductor device illustrated in FIG. 1 may correspond to modifications of a part of the operations for performing the method illustrated in FIGS. 5A through 5F. Thus, a repeated description thereof will not be provided here. For example, the operation of FIG. 7A may be performed after the operation of FIG. 5D.

Referring to FIG. 7A, a preparatory semiconductor material layer 301 is formed in the trenches T of FIG. 5D to fill them. The preparatory semiconductor material layer 301 may be an amorphous layer or a polycrystalline layer. The preparatory semiconductor material layer 301 may include silicon, silicon-germanium, or germanium. The preparatory semiconductor material layer 301 may be formed using CVD, LPCVD, PECVD, ALD, or sputtering.

Referring to FIG. 7B, the preparatory semiconductor material layer 301 is etched to form a first preparatory semiconductor layer 302a recessed in the trenches T. The first preparatory semiconductor layer 302a may be formed by etching the preparatory semiconductor material layer 301 by using the device isolation layer 210 as an etch mask. Alternatively, the first preparatory semiconductor layer 302a may be formed by forming a mask pattern layer (not shown) for exposing the preparatory semiconductor material layer 301 on the device isolation layer 210 and by etching the preparatory semiconductor material layer 301 by using the mask pattern layer as an etch mask.

Referring to FIG. 7C, a first single crystalline semiconductor layer 300a may be formed by phase-changing the first preparatory semiconductor layer 302a. The operation of forming the first single crystalline semiconductor layer 300a may be performed by phase-changing the first preparatory semiconductor layer 302a by annealing the first preparatory semiconductor layer 302a or by irradiating laser thereon. The annealing operation is as described above with reference to FIG. 5F. Also, a lower portion of the first single crystalline semiconductor layer 300a may include the polycrystalline layer and an upper portion of the first single crystalline semiconductor layer 300a may include the single crystalline layer, as described above with reference to FIG. 6.

Referring to FIG. 7D, a second preparatory semiconductor layer 302b is formed on the first single crystalline semiconductor layer 300a. The second preparatory semiconductor layer 302b may be formed by filling the trenches T. Although not shown, the second preparatory semiconductor layer 302b may be planarized so that the second preparatory semiconductor layer 302b and the device isolation layer 210 may be formed to the same height. The second preparatory semiconductor layer 302b may be an amorphous layer or a polycrystalline layer. The second preparatory semiconductor layer 302b may include silicon, silicon-germanium, or germanium. The second preparatory semiconductor layer 302b may be formed using CVD, LPCVD, PECVD, ALD, or sputtering. The first preparatory semiconductor layer 302a and the second preparatory semiconductor layer 302b may be formed of the same material or different materials. For example, the first preparatory semiconductor layer 302a may be formed of silicon, and the second preparatory semiconductor layer 302b may be formed of germanium or silicon-germanium. Alternatively, the first preparatory semiconductor layer 302a may be formed of germanium or silicon-germanium, and the second preparatory semiconductor layer 302b may be formed of silicon.

Referring to FIG. 7E, a second single crystalline semiconductor layer 300b is formed by phase-changing the second preparatory semiconductor layer 302b. The operation of forming the second single crystalline semiconductor layer 300b may be performed by phase-changing the second preparatory semiconductor layer 302b by annealing the second preparatory semiconductor layer 302b or by irradiating laser thereon. The annealing operation is as described above with reference to FIG. 5F. Also, the first single crystalline semiconductor layer 300a and the second single crystalline semiconductor layer 300b may constitute a single crystalline semiconductor layer 300.

The first single crystalline semiconductor layer 300a and the second single crystalline semiconductor layer 300b may have a crystalline structure in which the first single crystalline semiconductor layer 300a and the second single crystalline semiconductor layer 300b are coherent. For example, when the first single crystalline semiconductor layer 300a and the second single crystalline semiconductor layer 300b are formed of the same material, they may have a crystalline structure in which the first single crystalline semiconductor layer 300a and the second single crystalline semiconductor layer 300b formed of the same material having the same lattice size are coherent. On the other hand, when the first single crystalline semiconductor layer 300a and the second single crystalline semiconductor layer 300b are formed of different materials, they may have a crystalline structure in which the first single crystalline semiconductor layer 300a and the second single crystalline semiconductor layer 300b formed of different materials having different lattice sizes are coherent. When the first single crystalline semiconductor layer 300a is formed of silicon and the second single crystalline semiconductor layer 300b is formed of silicon-germanium, or germanium, one of the first single crystalline semiconductor layer 300a and the second single crystalline semiconductor layer 300b may be a strained layer due to the different lattice sizes of silicon and germanium.

Also, the second single crystalline semiconductor layer 300b may be formed by epitaxial single crystalline growth from the first single crystalline semiconductor layer 300a. In this case, the operation of forming the second preparatory semiconductor layer 302b and the operation of phase-changing the second preparatory semiconductor layer 302b may be omitted.

In the embodiment of FIGS. 7A through 7E, the first single crystalline semiconductor layer 300a and the second single crystalline semiconductor layer 300b are separately formed so that formation of voids in the single crystalline semiconductor layer 300 may be prevented and various semiconductor layers including the strained layer may be formed.

As described above, the case where the lower memory structures 120 and the upper memory structures 220 are NAND memory structures is exemplary, and the inventive concept is not limited thereto. For example, the lower memory structures 120 and the upper memory structures 220 may include NOR memory structures, DRAM memory structures, SRAM memory structures, MRAM memory structures, RRAM memory structures, and/or PRAM memory structures. Also, the lower memory structures 120 and the upper memory structures 220 may be different memory structures.

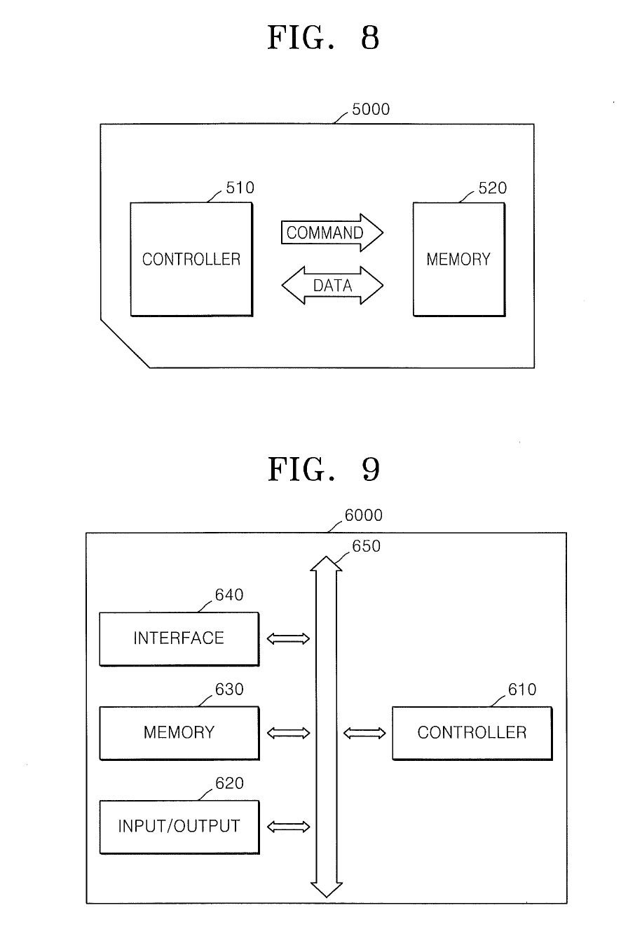

FIG. 8 is a schematic diagram of a memory card 5000 according to some embodiments of the inventive concept.

Referring to FIG. 8, a controller 510 and a memory 520 are disposed to send/receive electric signals to/from each other. For example, when the controller 510 provides a command to the memory 520, the memory 520 may send data. The memory 520 may include the stacked semiconductor device according to some embodiments of the inventive concept. The stacked semiconductor devices according to the various embodiments of the inventive concept may be disposed in NAND or NOR architecture arrays (not shown) in correspondence to the logic gate design. Such NAND and NOR arrays are generally known in the art. The memory arrays disposed in a plurality of rows and columns can have one or more memory array banks (not shown). The memory 520 may include the memory array (not shown) or the memory array bank (not shown), all of which are known in the art. The memory card 5000 may further include conventional elements, such as a conventional row decoder (not shown), a column decoder (not shown), input/output (I/O) buffers (now shown), and/or a control register (not shown) in order to drive the memory array bank (not shown), all of which are known in the art. The memory card 5000 may be used in memory devices as a memory card, for example, such as a memory stick card, a smart media (SM) card, a secure digital (SD) card, a mini SD card, or a multi media card (MMC), among others.

FIG. 9 is a schematic diagram of a system 6000 according to some embodiments of the inventive concept.

Referring to FIG. 9, the system 6000 may include a controller 610, an input/output device 620, a memory 630, and an interface 640. The system 6000 may be a mobile system or a system that transmits or receives data. The mobile system may be a personal digital assistant (PDA), a portable computer, a web tablet, a wireless phone, a mobile phone, a digital music player, or a memory card, among others. The controller 610 executes a software program and controls the system 6000. The controller 610 may be a microprocessor, a digital signal processor, a microcontroller, or the like. The input/output device 620 may be used to input or output data of the system 6000. The system 6000 is connected to an external apparatus (not shown), for example, a personal computer or a network, using the input/output device 620, to send/receive data to/from the external apparatus. The input/output device 620 may be a keypad, a keyboard, or a display. The memory 630 may store codes and/or data for operating the controller 610 and/or may store data processed by the controller 610. The memory 630 may include a stacked semiconductor device according to some embodiments of the present invention. The interface 640 may be a data transmission path between the system 6000 and another external apparatus. The controller 610, the input/output device 620, the memory 630, and the interface 640 may communicate with one another via a bus 650. For example, the system 6000 may be used for a mobile phone, a MP3 player, a navigation system, a portable multimedia player (PMP), a solid state disk (SSD), or a household appliance, among others.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

What is claimed is:

1. A method of manufacturing a stacked semiconductor device, the method comprising:
providing a lower memory layer comprising a plurality of lower memory structures;
forming an insulating layer on the lower memory layer;
forming trenches by removing portions of the insulating layer;
forming a preparatory semiconductor layer that is configured to fill the trenches; and
forming a single crystalline semiconductor layer by phase-changing the preparatory semiconductor layer,
wherein the single crystalline semiconductor layer comprises a lower portion comprising a polycrystalline layer having a plurality of crystalline regions and an upper portion comprising a single crystalline layer formed by growing one of the plurality of crystalline regions in a single crystalline manner in an upward direction.

2. The method of claim 1, wherein the preparatory semiconductor layer comprises an amorphous layer or a polycrystalline layer.

3. The method of claim 1, wherein the preparatory semiconductor layer comprises silicon, silicon-germanium, or germanium.

4. The method of claim 1, wherein forming the insulating layer comprises:
forming an etch stop layer on the lower memory layer; and
forming the insulating layer on the etch stop layer.

5. The method of claim 4, wherein forming the trenches comprises forming the trenches to expose the etch stop layer.

6. The method of claim 4, wherein the insulating layer and the etch stop layer have different etch selectivities.

7. The method of claim 4, wherein forming the etch stop layer on the lower memory layer comprises planarizing the etch stop layer.

8. The method of claim 1, wherein forming the single crystalline semiconductor layer comprises:
melting the preparatory semiconductor layer; and
growing single crystals from the melted preparatory semiconductor layer.

9. The method of claim 1, wherein forming the single crystalline semiconductor layer comprises forming the single crystalline semiconductor layer by annealing the preparatory semiconductor layer or by irradiating laser on the preparatory semiconductor layer.

10. The method of claim 1, wherein forming the single crystalline semiconductor layer comprises forming the single crystalline semiconductor layer by using laser epitaxial growth, solid phase-change epitaxy, or metal induced crystallization using a metal catalyst.

11. The method of claim 1, further comprising, after forming the single crystalline semiconductor layer, forming an upper memory layer comprising a plurality of upper memory structures for using the single crystalline semiconductor layer for active regions.

12. The method of claim 11, wherein the plurality of upper memory structures comprise NAND memory structures, NOR memory structures, dynamic random access memory (DRAM) memory structures, static RAM (SRAM) memory structures, magnetic RAM (MRAM) memory structures, resistive RAM (RRAM) memory structures, or phase change RAM (PRAM) memory structures.

13. The method of claim 1, wherein the plurality of lower memory structures comprise NAND memory structures, NOR memory structures, DRAM memory structures, SRAM memory structures, MRAM memory structures, RRAM memory structures, or PRAM memory structures.

14. A method of manufacturing a stacked semiconductor device, the method comprising:
providing a lower memory layer comprising a plurality of lower memory structures;
forming an insulating layer on the lower memory layer;
forming trenches by removing portions of the insulating layer;
forming a first preparatory semiconductor layer in portions of the trenches;
forming a first single crystalline semiconductor layer by phase-changing the first preparatory semiconductor layer;
forming a second preparatory semiconductor layer on the first single crystalline semiconductor layer in other respective portions of the trenches; and
forming a second single crystalline semiconductor layer by phase-changing the second preparatory semiconductor layer,
wherein the first single crystalline semiconductor layer comprises a lower portion comprising a polycrystalline layer having a plurality of crystalline regions and an upper portion comprising a single crystalline layer formed by growing one of the plurality of crystalline regions in a single crystalline manner in an upward direction.

15. The method of claim 14, wherein forming the first preparatory semiconductor layer comprises:
forming a preparatory semiconductor material layer in the trenches to fill the trenches; and
forming the first preparatory semiconductor layer recessed in the trenches by etching the preparatory semiconductor material layer.

16. The method of claim 14, wherein the second preparatory semiconductor layer is formed to fill the trenches.

17. The method of claim 14, wherein forming the first single crystalline semiconductor layer and the forming of the second single crystalline semiconductor layer comprise forming the first single crystalline semiconductor layer and forming the second single crystalline semiconductor layer insulating layer by respectively annealing the first preparatory semiconductor layer and the second preparatory semiconductor layer or by respectively irradiating laser on the first preparatory semiconductor layer and the second preparatory semiconductor layer.

18. The method of claim 14, wherein the first single crystalline semiconductor layer and the second single crystalline semiconductor layer have a crystalline structure in which the first single crystalline semiconductor layer and the second single crystalline semiconductor layer are coherent.

19. The method of claim 14, wherein one of the first single crystalline semiconductor layer and the second single crystalline semiconductor layer comprises a strained layer.

20. A method of manufacturing a stacked semiconductor device, the method comprising:
providing a semiconductor layer comprising a plurality of lower memory structures;
forming a preparatory semiconductor layer on the semiconductor layer; and
forming a single crystalline semiconductor layer by phase-changing the preparatory semiconductor layer,
wherein the single crystalline semiconductor layer comprises a lower portion comprising a polycrystalline layer having a plurality of crystalline regions and an upper portion comprising a single crystalline layer formed by growing one of the plurality of crystalline regions in a single crystalline manner in an upward direction.
